(19) United States
(12) Patent Application Publication
(10) Pub. No.: US 2024/0387168 A1
(43) Pub. Date: Nov. 21, 2024

(54) METHOD OF MANUFACTURING SEMICONDUCTOR ELEMENT BY USING ATOMIC LAYER ETCHING (ALE) PROCESS

(71) Applicant: SAMSUNG ELECTRONICS CO., LTD., Suwon-si (KR)

(72) Inventors: Jinwoo Park, Suwon-si (KR); Heeyeop Chae, Suwon-si (KR); Yongjae Kim, Suwon-si (KR); Sangwuk Park, Suwon-si (KR); Yuna Lee, Suwon-si (KR); Jihye Lee, Suwon-si (KR); Jungpyo Hong, Suwon-si (KR)

(73) Assignees: SAMSUNG ELECTRONICS CO., LTD., Suwon-si (KR); RESEARCH & BUSINESS FOUNDATION SUNGKYUNKWAN UNIVERSITY, Suwon-si (KR)

(21) Appl. No.: 18/624,788

(22) Filed: Apr. 2, 2024

(30) Foreign Application Priority Data
May 15, 2023 (KR) 10-2023-0062692

(51) Int. Cl. H01L 21/02; C23C 16/44; H01L 21/311

(52) U.S. Cl. CPC H01L 21/0228; C23C 16/4408; H01L 21/31116

(57) ABSTRACT

A method of manufacturing a semiconductor element includes placing a structure, the structure including a substrate and a first metal-containing film disposed on the substrate, fluorinating at least one atomic layer from an exposed surface of the first metal-containing film by supplying a fluorinating gas to the structure to form a fluorinated atomic layer, and etching the fluorinated atomic layer of the first metal-containing film by supplying an etching gas to the structure, wherein the etching gas includes an inert gas in a plasma state.

### CROSS-REFERENCE TO RELATED APPLICATION

This application is based on and claims priority to Korean Patent Application No. 10-2023-0062692, filed on May 15, 2023, in the Korean Intellectual Property Office, the disclosure of which is incorporated by reference herein in its entirety.

### BACKGROUND

The present disclosure relates to a method of manufacturing a semiconductor element by using an atomic layer etching (ALE) process.

As geometries of structures on semiconductor substrates have continued to shrink and types of the structures have evolved, etching problems have increased. To resolve such problems, a technique of atomic layer etching (ALE) may be used. Here, ALE may refer to a technique of etching a material layer with atomic precision.

### SUMMARY

The present disclosure provides a method of manufacturing a semiconductor element by using an ALE process, in which a surface roughness of a metal-containing film may be improved.

The present disclosure provides a method of manufacturing a semiconductor layer by using an ALE process, in which a thickness of a metal-containing film may be precisely adjusted.

The present disclosure is not limited to the objectives described above, and other objectives would be clearly understood by a person skilled in the art from the following descriptions.

According to the present disclosure, a method of manufacturing a semiconductor element includes placing a structure, the structure comprising a substrate and a first metal-containing film disposed on the substrate, fluorinating at least one atomic layer from an exposed surface of the first metal-containing film by supplying a fluorinating gas to the structure to form a fluorinated atomic layer, and etching the fluorinated atomic layer of the first metal-containing film by supplying an etching gas to the structure, wherein the etching gas includes an inert gas in a plasma state.

According to the present disclosure, a method of manufacturing a semiconductor element includes placing a sample in a process chamber of an etching device, the sample including a substrate and a metal-containing film disposed on the substrate, performing a first fluorination process by injecting a first fluorinating gas into the process chamber, performing a first etching process by injecting a first etching gas into the process chamber, performing a second fluorination process by injecting a second fluorinating gas into the process chamber, and performing a second etching process by injecting a second etching gas into the process chamber, wherein the first etching gas and the second etching gas each include an inert gas in a plasma state.

According to the present disclosure, a method of manufacturing a semiconductor element includes placing a sample in a process chamber of an etching device, the sample including a substrate, an element structure disposed on the substrate, and a metal-containing film disposed on the element structure, performing a first fluorination process by injecting a first fluorination gas into the process chamber, supplying a first purge gas to the process chamber, performing a first etching process by injecting a first etching gas into the process chamber, supplying a second purge gas to the process chamber, performing a second fluorination process by injecting a second fluorinating gas into the process chamber, supplying a third purge gas to the process chamber, performing a second etching process by injecting a second etching gas into the process chamber, and supplying a fourth purge gas to the process chamber, wherein the first etching gas and the second etching gas each include an inert gas in a plasma state.

According to the present disclosure, in the method of manufacturing a semiconductor element by using ALE process, fluorinating at least one atomic layer from an exposed surface of a metal-containing film to form a fluorinated atomic layer and etching the fluorinated atomic layer of the metal-containing film may be separated. Due to this, the thickness of the metal-containing film may be precisely adjusted at the level of an atomic size. In addition, due to these reasons, a surface roughness of the metal-containing film may be improved.

### BRIEF DESCRIPTION OF DRAWINGS

Embodiments of the present disclosure will be more clearly understood from the following detailed description taken in conjunction with the accompanying drawings in which:

FIG. 1 is a flowchart of a method of a manufacturing a semiconductor element by using an atomic layer etching (ALE) process, according to embodiments;

FIGS. 2A to 2C are cross-sectional views illustrating a method of manufacturing a semiconductor element by using an ALE process, according to a process order, according to an embodiment;

FIG. 3 is a flowchart of a method of manufacturing a semiconductor element by using an ALE process, according to embodiments;

FIGS. 4A to 4E are cross-sectional views illustrating a method of manufacturing a semiconductor element by using an ALE process, according to a process order, according to an embodiment;

FIG. 5 is a perspective view illustrating etching equipment for performing a method of manufacturing a semiconductor element by using an ALE process, according to a Comparative Example and an Example;

FIGS. 6A to 6C are graphs showing results of X-ray photoelectron spectroscopy (XPS) of Comparative Example 1, Experimental Example 1, and Experimental Example 2;

FIGS. 7A and 7B are graphs showing etch per cycle (EPC) in Experimental Example 3 and Experimental Example 4;

FIG. 8 is a graph showing XPS results of Comparative Example 2, Experimental Example 5, Experimental Example 6, Experimental Example 7, and Experimental Example 8;

FIGS. 9A and 9B are graphs showing XPS results of Comparative Example 3, Comparative Example 4, Comparative Example 5, and Experimental Example 9;

FIG. 10 shows photographs showing surfaces of Comparative Example 3, Comparative Example 4, Comparative Example 5, and Experimental Example 9, measured by an atomic force microscope (AFM) analysis method; and

FIGS. 11A to 11D are photographs of Comparative Example 3, Comparative Example 4, Comparative Example 5, and Experimental Example 9, respectively, by a transmission electron microscope (TEM).

### DETAILED DESCRIPTION

Hereinafter, embodiments are described in detail with reference to the accompanying drawings. In the drawings, the same reference characters are used for the same elements, and redundant descriptions thereof are omitted. Also, the phrases “at least one of A and B” and “at least one of A or B” have the same meaning as “A, B, or A and B.”

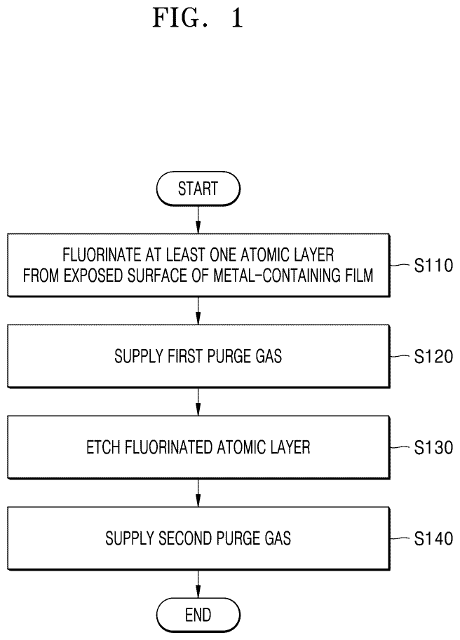

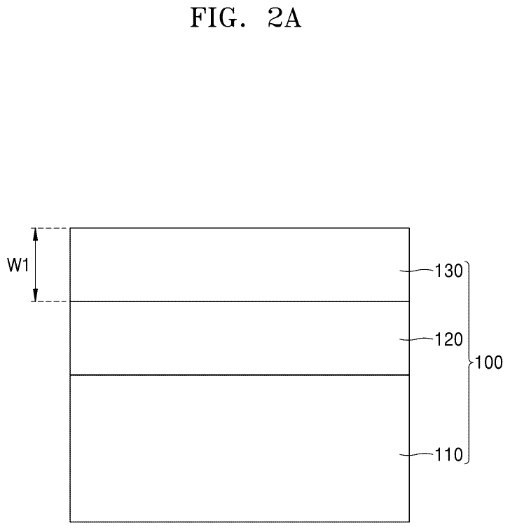

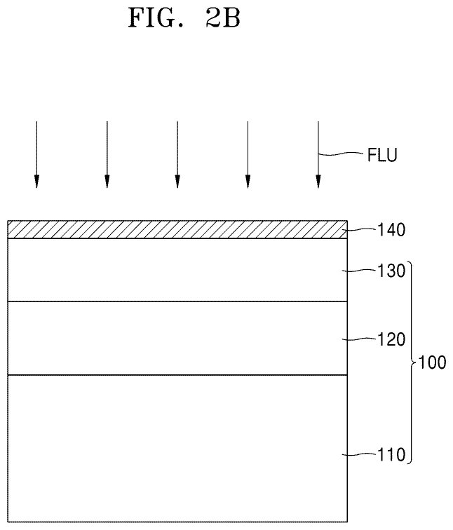

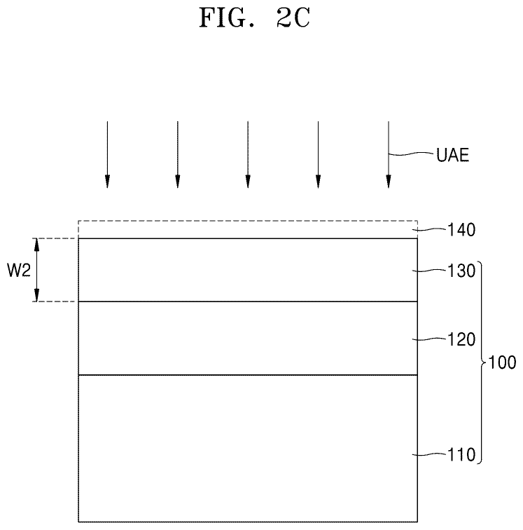

FIG. 1 is a flowchart of a method of manufacturing a semiconductor element by using an atomic layer etching (ALE) process, according to embodiments. FIGS. 2A to 2C are cross-sectional views illustrating a method of manufacturing a semiconductor element by using an ALE process according to a process order, according to an embodiment.

Referring to FIGS. 1, 2A, 2B, and 2C, a method of manufacturing a semiconductor element by using atomic layer etching (hereinafter, simply referred to as “ALE”) of the present embodiment may include, first, performing a process S110 of fluorinating at least one atomic layer from a surface of a first metal-containing film 130 formed on a substrate 110.

To perform the fluorination process S110, first, a structure 100 may be provided, as illustrated in FIG. 2A. The structure 100 may include the substrate 110, an element structure 120, and the first metal-containing film 130. The substrate 110 may include a semiconductor, such as silicon (Si) or germanium (Ge), or a compound semiconductor, such as silicon-germanium (SiGe), silicon carbide (SiC), gallium arsenide (GaAs), indium arsenide (InAs), indium gallium arsenide (InGaAs), or indium phosphide (InP). Terms such as “SiGe,” “SiC,” “GaAs,” “InAs,” “InGaAs,” and “InP” used herein refer to materials including elements included in the respective terms and are not chemical formulas that represent a stoichiometric relationship. Alternatively, the substrate 110 may have a silicon on insulator (SOI) structure. For example, the substrate 110 may include a buried oxide layer (BOX). In addition, the substrate 110 may include a conductive area, for example, a well doped with impurities or a structure doped with impurities. In addition, the substrate 110 may have various element isolation structures, such as a shallow trench isolation (STI) structure.

The element structure 120 may be provided on the substrate 110. The element structure 120 may include various element structures formed in a front-end-of-line (FEOL) process of the structure 100. For example, the element structure 120 may have a structure such as a dynamic random access memory (DRAM) cell transistor, a three-dimensional (3D) NAND flash memory, a fin field-effect transistor (FinFET), a multi-bridge channel field-effect transistor (MBCFET), a capacitor, or a transistor. In other words, the structure 100 may include various elements, depending on a structure included in the element structure 120.

The first metal-containing film 130 may be provided on the element structure 120. The first metal-containing film 130 may include a metal or a metal compound. For example, the metal of the first metal-containing film 130 may include a metal material, such as aluminum (Al), zirconium (Zr), iron (Fe), manganese (Mn), magnesium (Mg), chromium (Cr), silicon (Si), gallium (Ga), zinc (Zn), lead (Pb), germanium (Ge), tin (Sn), copper (Cu), titanium (Ti), tantalum (Ta), tungsten (W), molybdenum (Mo), ruthenium (Ru), rhodium (Rh), cobalt (Co), niobium (Nb), hafnium (Hf), nickel (Ni), platinum (Pt), ytterbium (Yb), terbium (Tb), dysprosium (Dy), erbium (Er), or palladium (Pd). For example, the metal compound of the first metal-containing film 130 may include SiGe, silicon nitride (Si₃N₄), titanium oxide (TiO₂), SiOCH, HfSiON, HfSiOₓ, LaAlOₓ, La₂O₃, LaSiOx, ZrO₂, TaN, TiN, Al₂O₃, HfO₂, etc. (x is a natural number). However, the first metal-containing film 130 is not limited to the examples described above. The first metal-containing film 130 may have a first width W1. Also, the first metal-containing film 130 may include a metal having a lower resistance than copper.

Referring to FIG. 2B, the fluorination process S110 may refer to supplying a fluorinating gas FLU onto the first metal-containing film 130 and converting part of an upper portion of the first metal-containing film 130 into a second metal-containing film 140. The fluorinating gas FLU may include at least one of hydrogen fluoride gas, fluorocarbon gas, nitrogen-containing gas, sulfur-containing gas, and chlorine-containing gas. For example, the fluorine gas FLU may include CₓF_{y}, CHFₓ, CHₓF_{y}, Cl₂, BCl₃, HBr, NF₃, and SF₆ (x and y are natural numbers). The second metal-containing film 140 may include at least one atomic layer of the first metal-containing film 130 that is fluorinated due to the fluorination process S110. The second metal-containing film 140 may include metal fluoride. For example, the second metal-containing film 140 may include a material such as molybdenum fluoride (MoF₆) or Mo₂CFₓ (x is a natural number). The second metal-containing film 140 may include the same material as the first metal-containing film 130.

The fluorinating gas FLU may be supplied to the second metal-containing film 140 in a plasma state. Plasma may contain various components, such as radicals, electrons, ions, ultraviolet rays, and neutrons. At least one of the components may be used in an etching process. Radicals may be electrically neutral, and ions may be electrically polar. Accordingly, when plasma is used in an etching process, radicals may be used to isotropically etch an object to be etched, and ions may be used to anisotropically etch an object to be etched. When radicals or ions are used in the etching process, other components excluding those components may be removed. Components that are not necessary in the etching process may be removed, and only radicals or ions required in the etching process may be supplied to an etching device.

Radicals or ions of the fluorinating gas FLU that are required in the etching process may react with the first metal-containing film 130, or may be molecularly deposited on the first metal-containing film 130. Through the process described above, the second metal-containing film 140 may be formed on the first metal-containing film 130. Radicals or ions of the fluorinating gas FLU react with the first metal-containing film 130, so that part of the upper portion of the first metal-containing film 130 may be changed to the second metal-containing film 140.

Meanwhile, the first metal-containing film 130 may be crystallized through heat treatment before the fluorination process S110. For example, the first metal-containing film 130 may be crystallized at less than or equal to 400° C. However, the crystallization temperature is not limited to the above numerical value.

After the fluorination process S110, a process S120 of supplying a first purge gas may be performed. An inner portion (e.g., a chamber) of etching equipment in which ALE is performed may be purged through the first purge gas to remove residual gas, by-products, etc. The first purge gas may include an inert gas, such as nitrogen gas (N₂), neon (Ne), argon (Ar), krypton (Kr), xenon (Xe), or radon (Rn).

Referring to FIGS. 1 and 2C, an etching process S130 may be performed. The etching process S130 may refer to supplying an etching gas UAE and making the etching gas UAE into a plasma state, and then applying a bias voltage to the inside of a process chamber and removing the second metal-containing film 140. The etching gas UAE that has entered the plasma state may move toward the substrate 110 by the bias voltage and collide with the second metal-containing film 140, to remove the second metal-containing film 140. The etching gas UAE may include an inert gas, such as N₂, Ne, Ar, Kr, Xe, or Rn.

After the etching process S130, a process S140 of supplying a second purge gas may be performed. The inside of the etching equipment in which the ALE process is in progress may be purged through the second purge gas to remove residual gas, by-products, etc. The second purge gas may include an inert gas, such as N₂, Ne, Ar, Kr, Xe, or Rn.

Thereafter, the second purge gas is discharged as exhaust gas, and the method of manufacturing the semiconductor element by using the ALE process is completed, and part of the upper portion of the first metal-containing film 130 may be removed. By adjusting a flow rate, time, pressure, etc. of the fluorinating gas FLU and the etching gas UAE, a thickness of the first metal-containing film 130 may be precisely controlled to the level of an atomic size. After the part of the upper portion of the first metal-containing film 130 is removed, the first metal-containing film 130 may have a second width W2. The second thickness W2 may be less than the first thickness W1 in FIG. 2A.

After the etching process S130 is performed, the second metal-containing film 140 may be completely removed. In an embodiment, after the etching process S130 is performed, part of the second metal-containing film 140 may remain. In this way, a semiconductor element may be manufactured.

A surface roughness of a metal may be an element that affects carrier transfer in nanoscale semiconductor elements, such as DRAM, 3D NAND flash memory, a FinFET, or an MBCFET. In addition, when the surface roughness is large, interfacial resistance increases, and electrical characteristics of a semiconductor element may deteriorate.

In the method of manufacturing the semiconductor element by using an ALE process, according to embodiments, the fluorination process S110 and the etching process S130 may be separated. In this case, by adjusting the flow rate, time, pressure, etc. of the fluorinating gas FLU and the etching gas UAE, the thickness of the first metal-containing film 130 may be precisely adjusted at the level of an atomic size. Due to these reasons, a surface roughness of the first metal-containing film 130 may be improved.

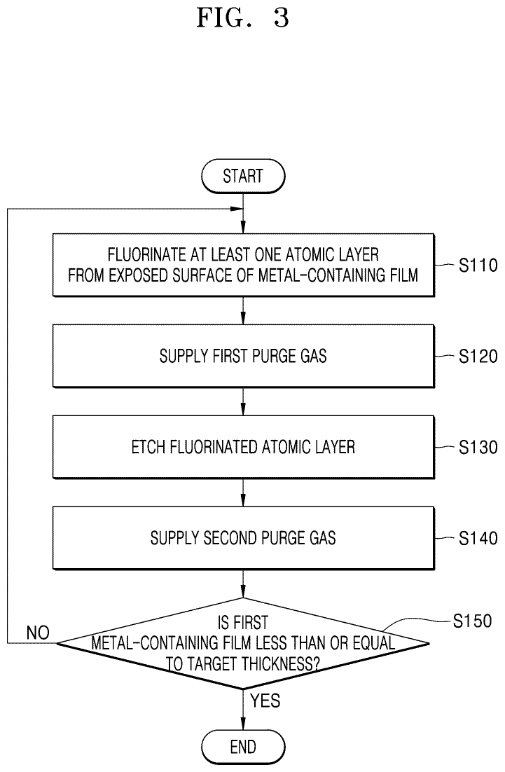

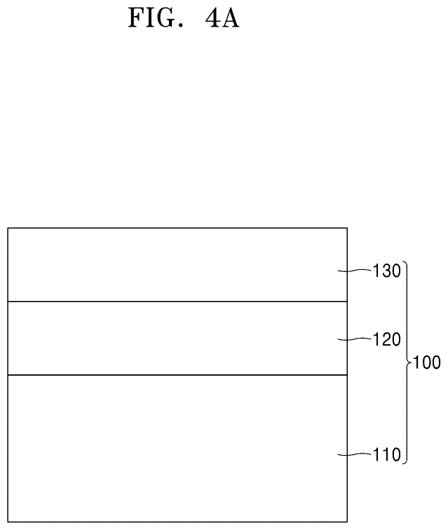

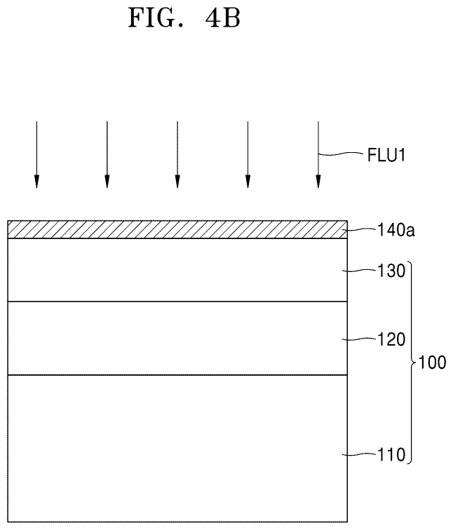

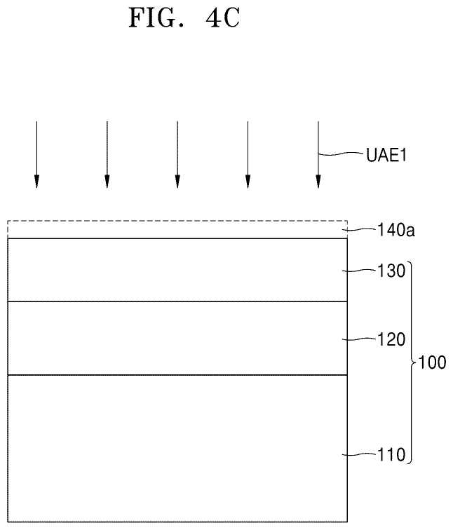

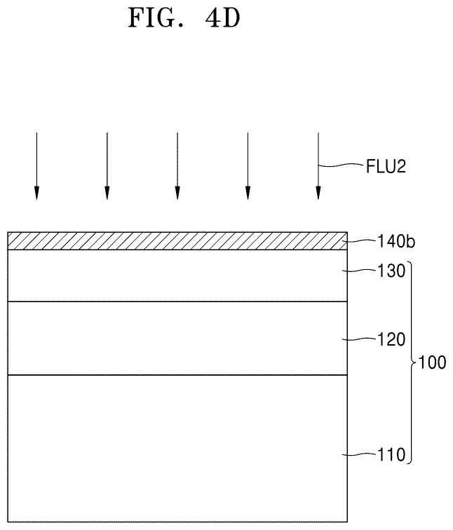

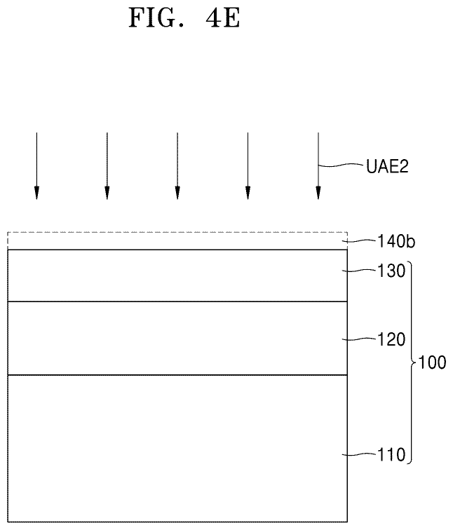

FIG. 3 is a flowchart of a method of manufacturing a semiconductor element by using an ALE process, according to embodiments. FIGS. 4A to 4E are cross-sectional views illustrating a method of manufacturing a semiconductor element by using an ALE process according to a process order, according to an embodiment.

Referring to FIG. 3, the method of manufacturing the semiconductor element by using the ALE process further includes a process S150 of determining whether a thickness of the first metal-containing film 130 is less than or equal to a target thickness, and thus may be different from the method of manufacturing the semiconductor element by using the ALE process in FIG. 1. Specifically, the method of manufacturing the semiconductor element by using the ALE process in this embodiment may further include the process S150 of determining whether the thickness of the first metal-containing film is less than or equal to the target thickness, after the operation S140 of supplying the second purge gas S140. Here, the target thickness may be, for example, about 50 Å. However, the target thickness is not limited to the above numerical value.

When the thickness of the first metal-containing film 130 is less than or equal to the target thickness (Yes), the method of manufacturing the semiconductor element by using the ALE process is terminated. However, when the thickness of the first metal-containing film 130 exceeds the target thickness (No), the process proceeds to the fluorination process S110. A process from the fluorination process S110 to the process S140 of supplying the second purge gas constitute one cycle of the method of manufacturing the semiconductor element by using the ALE process, and the cycle of the method of manufacturing the semiconductor element by using the ALE process may be continuously repeated until a dielectric film reaches a target thickness. Through this, the thickness of the first metal-containing film 130 may be precisely adjusted to the level of an atomic size.

Referring to FIG. 4A, a structure 100 may be provided, as described with reference to FIG. 2A. The substrate 100 may include a substrate 110, an element structure 120, and a first metal-containing film 130. The structure 100, the substrate 110, the element structure 120, and the first metal-containing film 130 in FIG. 4A may correspond to the structure 100, the substrate 110, the element structure 120, and the first metal-containing film 130 in FIGS. 2A to 2C, respectively.

Referring to FIGS. 3 and 4B, the method of manufacturing the semiconductor element by using the ALE process in this embodiment may include performing a process S110 of fluorinating at least one atomic layer from a surface of the first metal-containing film 130 of the structure 100.

The fluorination process S110 may refer to a process of supplying a first fluorinating gas FLU1 on the first metal-containing film 130 and converting part of an upper portion of the first metal-containing film 130 into a third metal-containing film 140a. The first fluorinating gas FLU1 and the third metal-containing film 140a in FIG. 4B may correspond to the fluorinating gas FLU and the second metal-containing film 140 in FIG. 2B, respectively.

After the fluorination process, a process S120 of supplying a first purge gas may be performed. The first purge gas may correspond to the first purge gas used in regard to FIG. 2B.

Referring to FIGS. 3 and 4C, the etching process S130 is continuously performed. The etching process S130 may refer to a process of supplying a first etching gas UAE1 and making the first etching gas UAE1 into a plasma state, and then applying a bias voltage to the inside of a process chamber and removing the third metal-containing film 140a. The first etching gas UAE1 may correspond to the etching gas UAE in FIG. 2C.

After the etching process S130, a process S140 of supplying a second purge gas may be performed. The second purge gas may correspond to the second purge gas used in regard to FIG. 2C.

Referring to FIGS. 3 and 4D, when a thickness of the first metal-containing film 130 is not less than or equal to a target thickness (No), the process may proceed to the fluorination process S110 again. As in FIG. 4D, a second fluorinating gas FLU2 may be supplied onto the first metal-containing film 130, so as to convert part of an upper portion of the first metal-containing film 130 into a fourth metal-containing film 140b. The second fluorinating gas FLU2 may correspond to the fluorinating gas FLU in FIG. 2B. The second fluorinating gas FLU2 may include the same material as the first fluorinating gas FLU1, or may include a material different from a material of the first fluorinating gas FLU1. The fourth metal-containing film 140b may correspond to the second metal-containing film 140 in FIGS. 2B to 2C. The fourth metal-containing film 140b may include the same material as the third metal-containing film 140a, or may include a material different from a material of the third metal-containing film 140a.

After the fluorination process S110, a process S120 of supplying a third purge gas may be performed. The third purge gas may correspond to the first purge gas used in regard to FIG. 2B.

Referring to FIGS. 3 and 4E, the etching process S130 may be continuously performed. The etching process S130 may refer to a process of supplying a second etching gas UAE2 and making the second etching gas UAE2 into a plasma state, and then applying a bias voltage to the inside of a process chamber and removing the fourth metal-containing film 140b. The second etching gas UAE2 may correspond to the etching gas UAE in FIG. 2C. The second etching gas UAE2 may include the same material as the first etching gas UAE1, or may include a material different from a material of the first etching gas UAE1.

After the etching process S130, a process S140 of supplying a fourth purge gas may be performed. The fourth purge gas may correspond to the second purge gas used in regard to FIG. 2C.

Meanwhile, the first purge gas, the first etching gas UAE1, and the second purge gas may include the same material as each other. In addition, the third purge gas, the second etching gas UAE2, and the fourth purge gas may include the same material as each other. Due to the above, when a purge operation-etching operation-purge operation process is performed, it is not necessary to change a type of gas being supplied, and thus, a time of the method of manufacturing the semiconductor by using the ALE process may be shortened.

Referring to FIG. 3, it is determined whether a thickness of the first metal-containing film 130 is less than or equal to a target thickness in operation S150. When the thickness of the first metal-containing film 130 is less than or equal to the target thickness, the method of manufacturing the semiconductor element by using the ALE process is terminated.

In the example above, it is described that the method of FIGS. 4A to 4C is performed once, and the method of FIGS. 4D and 4E is performed once. However, the method of FIGS. 4D and 4E may also be performed after the manufacturing method of FIGS. 4A to 4C is performed a plurality of times. In other words, after the manufacturing method from the fluorination process S110 to the supplying S140 of the second purge gas is performed a plurality of times by using the first fluorinating gas FLU1 and the first etching gas UAE1, the manufacturing method from the fluorination process S110 to the supplying S140 of the second purge gas may be performed by using the second fluorinating gas FLU2 and the second etching gas UAE2. However, the method of FIGS. 4D and 4E may also be performed a plurality of times.

According to an embodiment, the first fluorinating gas FLU1 may include a material having a higher fluorine content (i.e., a larger number of fluorine atoms) than the second fluorinating gas FLU2. For example, the first fluorinating gas FLU1 may include C₄F₈, and the second fluorinating gas FLU2 may include CHF₃.

When a gas having a large fluorine content is used in the fluorination process S110, a portion of the upper portion of the first metal-containing film 130 that is fluorinated (i.e., the second metal-containing film 140 in FIG. 2B) may be large compared to a case in which a gas having a small fluorine content is used. In other words, a gas having a large fluorine content is used in the fluorination process S110, a thickness of the third metal-containing film 140a formed from the first metal-containing film 130 may be greater than a case in which a gas having a small fluorine content is used. When a thickness of the third metal-containing film 140a increases, an etching process per cycle of a method of manufacturing a semiconductor element by using an ALE process may be further increased. On the other hand, when a gas having a small fluorine content is used, an etching thickness per cycle of the method of manufacturing the semiconductor element by using the ALE process may be further reduced. Accordingly, after quickly reducing the thickness of the first metal-containing film 130 by first using the first fluorinating gas FLU1 having a large fluorine content, the second fluorinating gas FLU2 having a small fluorine content may be used to precisely adjust the thickness of the first metal-containing film 130.

Next, the disclosure is described in greater detail through experimental examples. However, experimental examples described below are to describe the disclosure in greater detail, and the scope of the technical idea of the disclosure is not to be limited by the experimental examples described below.

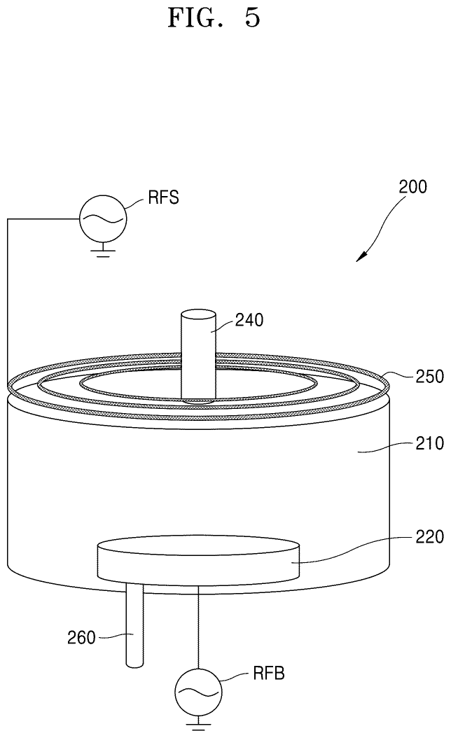

FIG. 5 is a perspective view illustrating etching equipment for performing a method of manufacturing a semiconductor element by using an ALE process according to Comparative Examples and Experimental Examples.

Referring to FIG. 5, an etching device 200 for conducting the Experimental Examples and Comparative Examples is provided. The etching device 200 may include a process chamber 210, an electrostatic chuck 220, a gas inlet 240, an induction coil 250, a source voltage generator RFS, a bias voltage generator RFB, and a gas outlet 260. In an embodiment, the etching device 200 may be inductively coupled plasma (ICP) equipment.

The electrostatic chuck 220 may be provided inside the process chamber 210. The process chamber 210 may be a space in which a method of manufacturing a semiconductor element by using an ALE process is performed. The electrostatic chuck 220 may perform a function of fixing a sample in the process chamber 210 by using an electrostatic force. The sample is an experimental subject in which a method of manufacturing a semiconductor element by using an ALE process is performed. The sample may include Mo. The sample may correspond to the first metal-containing film 130 described with reference to FIGS. 2A to 2C.

The gas inlet 240 may be a passage through which gases used in the method of manufacturing the semiconductor element by using the ALE process are supplied into the process chamber 210. The fluorinating gas FLU, the first purge gas, the etching gas UAE, the second purge gas, etc. described with reference to FIGS. 2A to 2C may be supplied to the inside of the process chamber 210 through the gas inlet 240.

The induction coil 250 may perform a function of making the fluorinating gas FLU and the etching gas UAE into a plasma state. Specifically, when an indirect current voltage is applied to the induction coil 250 via the source voltage generator RFS connected to the induction coil 250, a magnetic field is generated, thereby forming an induction electric field again. In addition, electrons accelerated by the induction electric field collide with the fluorinating gas FLU and the etching gas UAE to generate plasma. The plasma may be generated outside the process chamber 210 and supplied to the inside of the process chamber 210, or may be generated inside the process chamber 210. Thereafter, a voltage may be applied to the bias voltage generator RFB electrically connected to the sample to supply the plasma to the sample. After the reaction proceeds, residues may be discharged to the outside through the gas outlet 260.

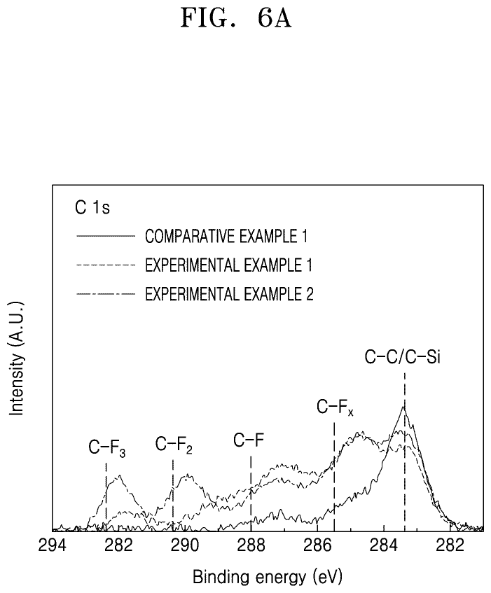

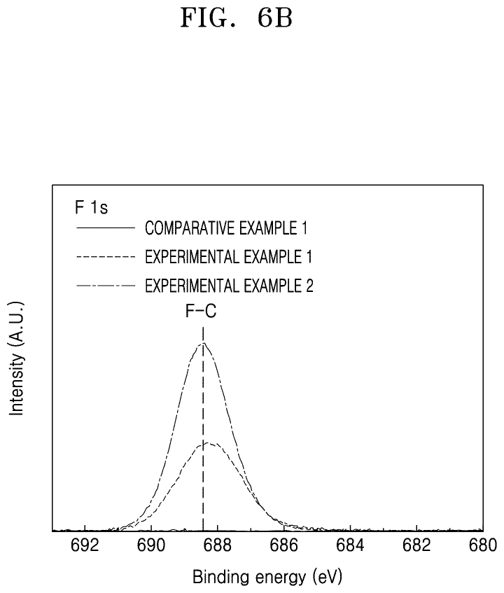

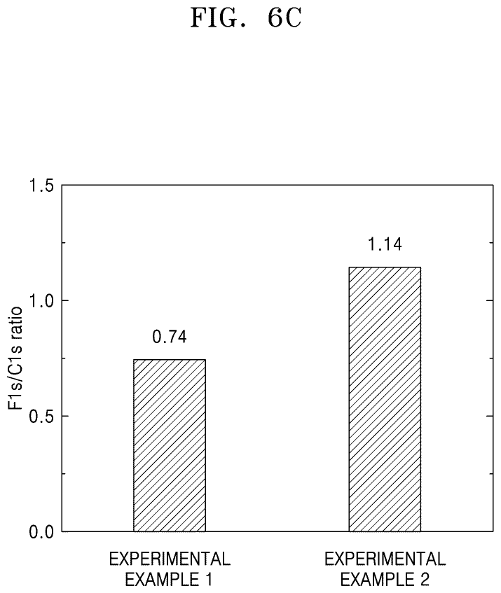

FIGS. 6A to 6C are graphs showing X-ray photoelectron spectroscopy (XPS) results of Comparative Example 1, Experimental Example 1, and Experimental Example 2.

Referring to FIGS. 5, 6A, 6B, and 6C, the XPS results of Comparative Example 1, Experimental Example 1, and Experimental Example 2 may be compared.

In Comparative Example 1, no treatment was performed on a sample containing Mo.

In Experimental Example 1, a process described below was performed on the sample containing Mo.

1. Pressure of the process chamber 210 was adjusted to 1×10⁻⁴ Torr, and the sample was located on the electrostatic chuck 220.

2. 40 sccm of CHF₃ gas was supplied into the process chamber 210 for 30 seconds.

3. 25 W of source power was supplied through the source voltage generator RFS to make CHF₃ gas into plasma. In this case, a thickness of a new film formed on the sample due to the plasma was maintained at 1.0 nm.

In Experimental Example 2, the CHF₃ gas was changed to only C₄F₈ gas in the process of Experimental Example 1, and the same process was performed for the rest of the conditions.

Samples of Comparative Example 1, Experimental Example 1, and Experimental Example 2 were each analyzed by XPS. Referring to FIG. 6A, in the XPS results, a C1s peak is fitted with C—C/C—Si at 283.4 eV, C—CFₓ at 285.5 eV (x is a natural number), C—F at 288.0 eV, C—F₂ at 290.3 eV, and C—F₃ at 292.6 eV. Referring to FIG. 6B, an F1s peak was fitted with F—C at 688.3 eV.

Referring to FIGS. 5 and 6A, in Comparative Example 1, a high peak occurred at C—C/C—Si, whereas a low or almost no peak occurred at C—CFₓ, C—F, C—F₂, and C—F₃. On the other hand, in Experimental Examples 1 and 2, a high peak occurred at C—CFₓ, C—F, C—F₂, and C—F₃, and it can be analyzed that a fluorocarbon layer was formed on the sample surface.

Referring to FIGS. 5 and 6B, Experimental Example 2 was found to have a higher F—C peak than Experimental Example 1. This means that the sample in Experimental Example 2 had more fluorine content on the surface than the sample in Experimental Example 1. Specifically, it is analyzed that the plasma made from C₄F₈ gas contains more radicals of CₓF_{y} (x and y are natural numbers), such as C₂F₄ and C₃F₅, than the plasma made from CHF₃ gas.

Referring to FIG. 6C, a ratio of F1s/C1s can be seen in Experimental Example 1 and Experimental Example 2. The higher the ratio of F1s/C1s, the higher the fluorine content. The ratio of F1s/C1s in Experimental Example 2 was 1.14, and the ratio of F1s/C1s in Experimental Example 1 was 0.74. In other words, the ratio of F1s/C1s in Experimental Example 2 was greater than the ratio of F1s/C1s in Experimental Example 1. As described with reference to FIG. 5B, the result of FIG. 5C means that, in Experimental Example 2, a fluorocarbon layer containing more fluorine is formed on the sample surface than in Experimental Example 1.

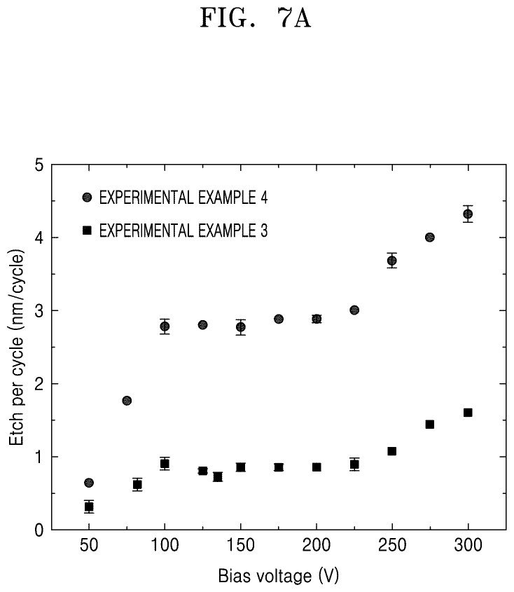

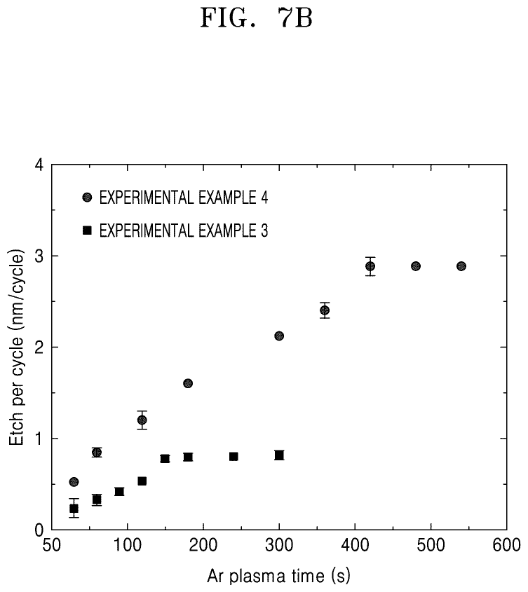

FIGS. 7A and 7B are graphs showing etch per cycle (EPC) in Experimental Example 3 and Experimental Example 4.

Referring to FIGS. 5, 7A, and 7B, an EPC of Experimental Examples 3 and 4 can be found.

In Experimental Example 3, a process described below was further performed on the sample in Experimental Example 1.

4. After a CHF₃ plasma gas was discharged, 40 sccm of Ar was supplied into the process chamber 210 for 30 seconds.

5. 25 W of source power was supplied through the source voltage generator RFS to make Ar gas into plasma. Thereafter, a bias power of 25 W was supplied through the bias voltage generator RFB so that the surface of the sample could be etched.

6. After the Ar plasma gas was discharged, 40 sccm of Ar was supplied into the process chamber 210 for 30 seconds.

In Experimental Example 4, compared to the process of Experimental Example 3, the CHF₃ gas was only changed to C₄F₈ gas, and the process was performed under the same conditions.

Referring to FIGS. 5 and 7A, a result of measuring a value of EPC when the bias voltage was applied to Experimental Example 3 and Experimental Example 4 can be seen. In both Experimental Example 3 and Experimental Example 4, in a period in which a bias voltage applied to the bias voltage generator RFB was in the range of 0 V to 100 V, EPC linearly increased, in a period in which the bias voltage was in the range of 100 V to 225 V, EPC remained constant, and in a period in which the bias voltage exceeded 225 V, EPC linearly increased again. In the period in which the bias voltage applied to the bias voltage generator RFB was in the range of 100 V to 225 V, EPC was 0.8 nm/cycle in Experimental Example 3 and 2.8 nm/cycle in Experimental Example 4. The EPC in Experimental Example 4 was about 3 times greater than the EPC in Experimental Example 3. This is due to the formation of a fluorocarbon layer containing a high fluorine content on the surface of the sample in Experimental Example 4.

Referring to FIGS. 5 and 7B, a result of measuring a value of EPC according to a time at which Ar plasma was supplied in Experimental Example 3 and Experimental Example 4 can be seen. In both Experimental Example 3 and Experimental Example 4, the bias voltage applied to the bias voltage generator RFB was fixed to 150 V. In Experimental Example 3, the EPC increased linearly until a time for supplying the Ar plasma reached 150 seconds, and after 150 seconds, the EPC had a constant value of 0.8 nm/cycle. In Experimental Example 4, the EPC increased linearly until the time for supplying the Ar plasma reached 420 seconds, and after 420 seconds, the EPC had a constant value of 2.8 nm/cycle. The reason why the EPC became constant when the Ar plasma supply time exceeded a certain value may be due to the fact that energy of the Ar plasma is sufficient to remove the fluorocarbon layer formed on the surface of the sample, but is not enough to remove a Mo metal. Thus, when the Ar plasma is used, it can be seen that an ALE process has a self-limiting characteristic with respect to the Ar plasma supply time.

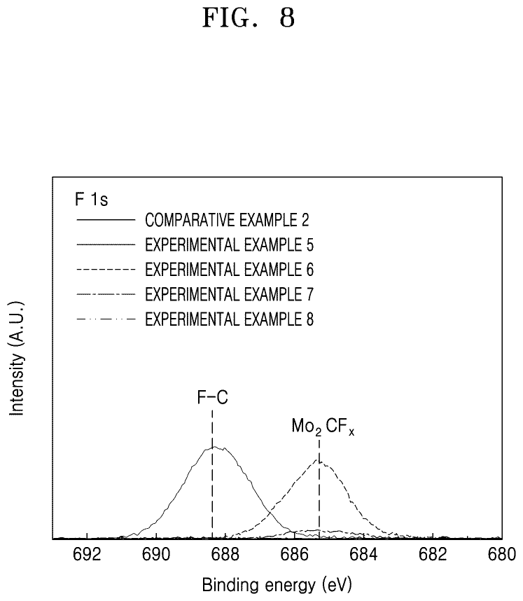

FIG. 8 is a graph showing XPS results of Comparative Example 2, Experimental Example 5, Experimental Example 6, Experimental Example 7, and Experimental Example 8.

Referring to FIGS. 5 and 8, the XPS results of Comparative Example 2, Experimental Example 5, Experimental Example 6, Experimental Example 7, and Experimental Example 8 can be seen.

Comparative Example 2 was the same as Comparative Example 1.

Experimental Example 5 was the same as Experimental Example 1.

In Experimental Example 6, a bias voltage of 50 V was applied to the Ar plasma in Experimental Example 3.

In Experimental Example 7, a bias voltage of 150 V was applied to the Ar plasma in Experimental Example 3.

In Experimental Example 8, a bias voltage of 300 V was applied to the Ar plasma in Experimental Example 3.

In Comparative Example 2, an F—C peak and a Mo₂CFₓ (x is a natural number) peak were not observed. In Experimental Example 5, the F—C peak was observed at 688.3 eV, and the Mo₂CFₓ peak was observed with very little intensity. In Experimental Example 6, the F—C peak disappeared, and the Mo₂CFₓ peak was strongly observed at 685.3 eV. In Experimental Example 7, the F—C peak not only disappeared, but also the intensity of Mo₂CFₓ peak decreased significantly. In Experimental Example 8, the F—C peak and the Mo₂CFₓ peak were not observed.

As can be seen in Experimental Example 6, when the bias voltage applied to the Ar plasma through the bias voltage generator RFB was in the range of 0 V to 100 V, it may be analyzed that the fluorocarbon layer on the sample surface had not completely been removed.

As can be seen in Experimental Example 7 and Experimental Example 8, when the bias voltage applied to the Ar plasma through the bias voltage RFB was greater than or equal to 100 V, it can be seen that the fluorocarbon layer had been effectively removed.

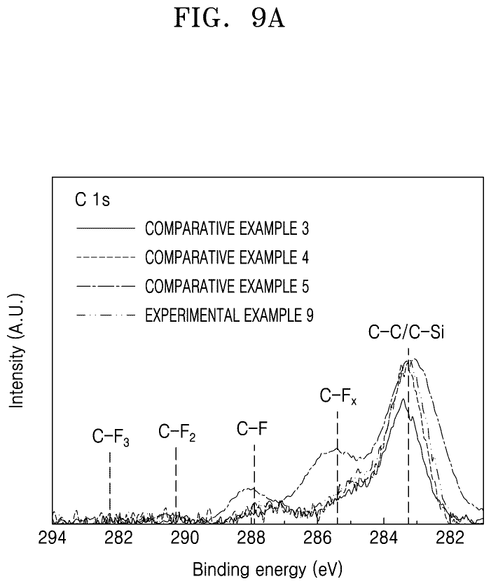

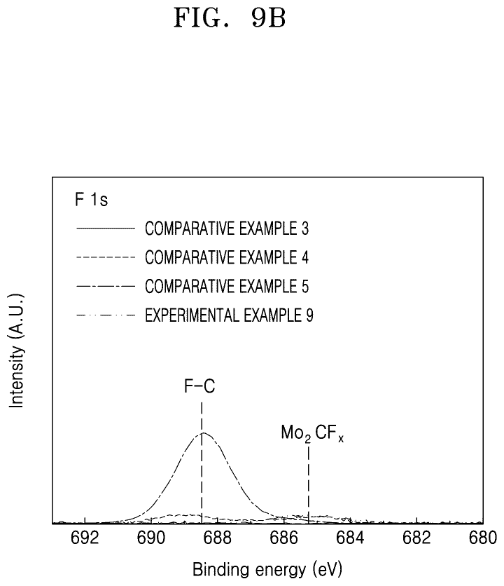

FIGS. 9A and 9B are graphs showing each of XPS results of Comparative Example 3, Comparative Example 4, Comparative Example 5, and Experimental Example 9.

Referring to FIGS. 5, 9A, and 9B, the XPS results of Comparative Example 3, Comparative Example 4, Comparative Example 5, and Experimental Example 9 can be seen.

Comparative Example 3 was the same as Comparative Example 1.

In Comparative Example 4, the process described below was performed on a sample containing Mo.

1. Pressure of the process chamber 210 was adjusted to 1×10⁻⁴ Torr, and the sample was placed on the electrostatic chuck 220.

2. 40 sccm of CF₄ gas was supplied into the process chamber 210 for 30 seconds.

3. 25 W of source power was supplied through the source voltage generator RFS to make CF₄ gas into plasma. The bias voltage was not applied.

4. After the CF₄ gas was discharged, 40 sccm of Ar was supplied into the process chamber 210 for 30 seconds.

In Comparative Example 5, the process described below was performed on a sample containing Mo.

1. The pressure of the process chamber 210 was adjusted to 1×10⁻⁴ Torr, and the sample was located on the electrostatic chuck 220.

2. 40 sccm of CHF₃ and Ar gas were supplied into the process chamber 210 for 30 seconds.

3. 25 W of source power was supplied through the source voltage generator RFS to make CHF₃ and Ar gas into plasma together. A bias voltage of 300 V was applied.

4. After the CHF₃ and Ar gas were discharged, 40 sccm of Ar was supplied into the process chamber 210 for 30 seconds.

Experimental Example 9 was the same as Experimental Example 7.

Comparative Example 4 may be referred to as a radical etching process, and Comparative Example 5 may be referred to as a reactive ion etching (RIE) process.

In Comparative Example 4, C1s and F1s peak intensities were similar to those of Comparative Example 3. This signifies that in Comparative Example 4, the fluorocarbon layer on the sample surface had been well etched. This is analyzed to be due to the fact that the CF₄ plasma easily chemically reacted with Mo by providing radicals containing a large amount of fluorine.

In Comparative Example 5, strong C—F, C—Fₓ, and F—C peaks were observed, and this means that the fluorocarbon layer on the sample surface had not been well etched.

In Experimental Example 9, the C1s and F1s peak intensities were similar to those of Comparative Example 3, except for a small Mo₂CFₓ (x is a natural number) peak as shown in FIG. 9B. In Experimental Example 9, a concentration of fluorine compounds in the sample was detected to be less than 4%. This means that in Experimental Example 9, the fluorocarbon layer on the sample surface had been well etched.

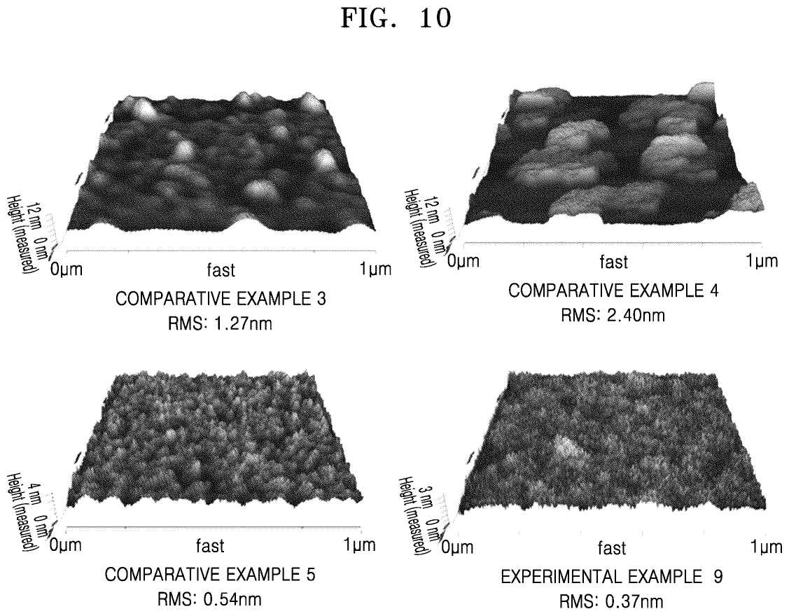

FIG. 10 shows photographs showing surfaces of Comparative Example 3, Comparative Example 4, Comparative Example 5, and Experimental Example 9, measured by using an atomic force microscopy (AFM) analysis method.

Referring to FIGS. 5 and 10, it may be observed that a surface roughness of Experimental Example 9 was reduced compared to Comparative Example 3, Comparative Example 4, and Comparative Example 5. The surface roughness of each of samples of Comparative Example 3, Comparative Example 4, Comparative Example 5, and Experimental Example 9 was measured by AFM. A root mean square surface roughness (RMS) of the sample was measured over a 1×1 μm² inspection area. The RMS was measured at 1.27 nm in Comparative Example 3, 2.40 nm in Comparative Example 4, 0.54 nm in Comparative Example 5, and 0.37 nm in Experimental Example 9.

As can be seen in Experimental Example 9, compared to Comparative Examples 4 and 5, when a method of manufacturing a semiconductor element by using an ALE process is used, it can be seen that the surface roughness was significantly improved compared to a radical etching process and an RIE process.

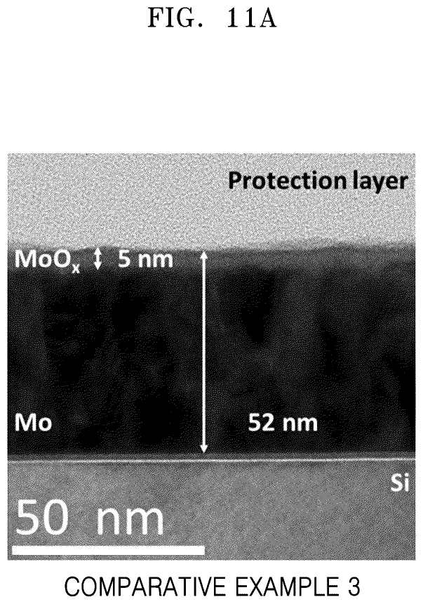

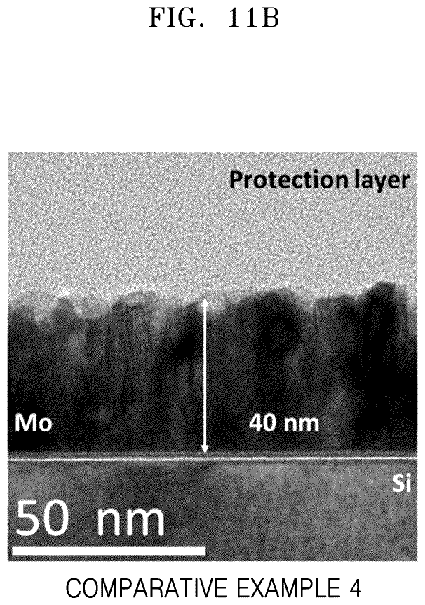

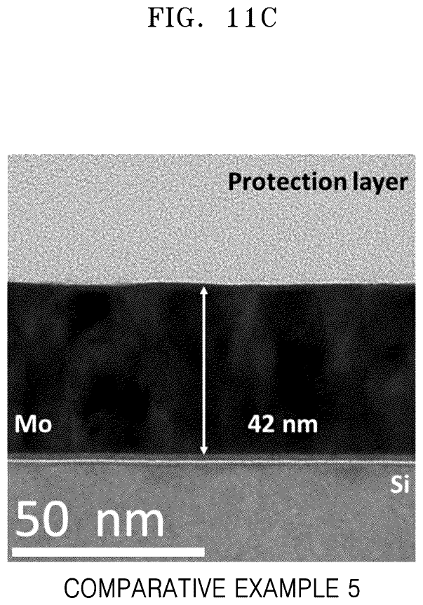

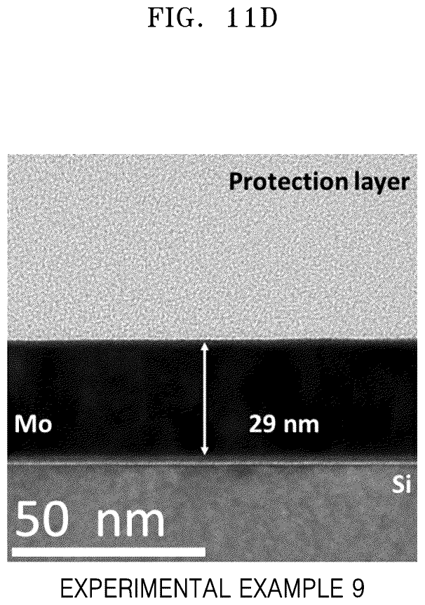

FIGS. 11A to 11D are photographs of Comparative Example 3, Comparative Example 4, Comparative Example 5, and Experimental Example 9, taken by a transmission electron microscope (TEM).

Referring to FIGS. 5, 11A, 11B, 11C, and 11D, it can be seen that the surface of the sample is smoother in the image of Experimental Example 9 than Comparative Example 3, Comparative Example 4, and Comparative Example 5.

While the present disclosure has been particularly shown and described with reference to embodiments thereof, it will be understood that various changes in form and details may be made therein without departing from the spirit and scope of the following claims.

What is claimed is:

1. A method of manufacturing a semiconductor element, the method comprising:
placing a structure, the structure comprising a substrate and a first metal-containing film disposed on the substrate;
fluorinating at least one atomic layer from an exposed surface of the first metal-containing film by supplying a fluorinating gas to the structure to form a fluorinated atomic layer; and
etching the fluorinated atomic layer of the first metal-containing film by supplying an etching gas to the structure,
wherein the etching gas comprises an inert gas in a plasma state.

2. The method of claim 1, wherein the fluorinating gas comprises a fluorocarbon gas.

3. The method of claim 2, wherein the fluorinating gas comprises trifluoromethane (CHF₃) or octafluorocyclobutane (C₄F₈).

4. The method of claim 1, wherein the fluorinating of the at least one atomic layer comprises supplying at least one of trifluoromethane (CHF₃) or octafluorocyclobutane (C₄F₈) as the fluorinating gas,
wherein
when CHF₃ is used as the fluorinating gas, the etching is performed for a first amount of time,
when C₄F₈ is used as the fluorinating gas, the etching is performed for a second amount of time, and
the second amount of time is greater than the first amount of time.

5. The method of claim 1, further comprising, after the fluorinating and the etching, supplying a purge gas to the structure.

6. The method of claim 1, wherein the first metal-containing film comprises a metal having a lower resistance than copper.

7. The method of claim 1, wherein the first metal-containing film comprises at least one of aluminum (Al), zirconium (Zr), iron (Fe), manganese (Mn), magnesium (Mg), chromium (Cr), silicon (Si), gallium (Ga), zinc (Zn), lead (Pb), germanium (Ge), tin (Sn), copper (Cu), titanium (Ti), tantalum (Ta), tungsten (W), molybdenum (Mo), ruthenium (Ru), rhodium (Rh), cobalt (Co), niobium (Nb), hafnium (Hf), nickel (Ni), platinum (Pt), ytterbium (Yb), terbium (Tb), dysprosium (Dy), erbium (Er), palladium (Pd), silicon-germanium (SiGe), silicon nitride (Si₃N₄), titanium oxide (TiO₂), SiOCH, hafnium silicon oxynitride (HfSiON), hafnium silicon oxide (HfSiOₓ), lanthanum aluminum oxide (LaAlOₓ), lanthanum oxide (La₂O₃), lanthanum silicon oxide (LaSiOx), zirconium oxide (ZrO₂), tantalum nitride (TaN), titanium nitride (TiN), aluminum oxide (Al₂O₃), and hafnium oxide (HfO₂) (x is a natural number).

8. The method of claim 1, wherein the fluorinating gas is in a plasma state.

9. The method of claim 1, wherein the fluorinating and the etching are repeated until a thickness of the first metal-containing film reaches a preset target thickness.

10. The method of claim 1, wherein, after the fluorinating, the fluorinated atomic layer comprises a second metal-containing film, and
after the etching, at least a portion of the second metal-containing film remains.

11. The method of claim 10, wherein the second metal-containing film comprises the same material as the first metal-containing film.

12. The method of claim 10, wherein the second metal-containing film comprises at least one of molybdenum fluoride (MoF₆) and molybdenum carbon fluoride (Mo₂CFₓ) (x is a natural number).

13. A method of manufacturing a semiconductor element, the method comprising:
placing a sample in a process chamber of an etching device, the sample comprising a substrate and a metal-containing film disposed on the substrate;
performing a first fluorination process by injecting a first fluorinating gas into the process chamber;
performing a first etching process by injecting a first etching gas into the process chamber;
performing a second fluorination process by injecting a second fluorinating gas into the process chamber; and
performing a second etching process by injecting a second etching gas into the process chamber,
wherein the first etching gas and the second etching gas each comprise an inert gas in a plasma state.

14. The method of claim 13, wherein the first fluorinating gas and the second fluorinating gas are different from each other.

15. The method of claim 13, wherein the first fluorinating gas comprises a gas having a higher fluorine content than the second fluorinating gas.

16. The method of claim 15, wherein the performing of the first etching process is performed for a first amount of time,
the performing of the second etching process is performed for a second amount of time, and
the first amount of time is greater than the second amount of time.

17. The method of claim 15, wherein the first fluorination process and the first etching process are performed before the second fluorination process and the second etching process.

18. The method of claim 16, wherein each of the first fluorination process and the first etching process are performed a plurality of times.

19. A method of manufacturing a semiconductor element, the method comprising:
placing a sample in a process chamber of an etching device, the sample comprising a substrate, an element structure disposed on the substrate, and a metal-containing film disposed on the element structure;
performing a first fluorination process by injecting a first fluorination gas into the process chamber;
supplying a first purge gas to the process chamber;
performing a first etching process by injecting a first etching gas into the process chamber;
supplying a second purge gas to the process chamber;
performing a second fluorination process by injecting a second fluorinating gas into the process chamber;
supplying a third purge gas to the process chamber;
performing a second etching process by injecting a second etching gas into the process chamber; and
supplying a fourth purge gas to the process chamber,
wherein the first etching gas and the second etching gas each comprise an inert gas in a plasma state.

20. The method of claim 19, wherein the first purge gas, the first etching gas, and the second purge gas comprise the same material as each other, and
the third purge gas, the second etching gas, and the fourth purge gas comprise the same material as each other.
